(19) United States
(12) Patent Application Publication
(10) Pub. No.: US 2024/0142871 A1
(43) Pub. Date: May 2, 2024

(54) MEMBRANE CLEANING APPARATUS

(71) Applicant: ASML NETHERLANDS B.V., Veldhoven (NL)

(72) Inventors: Andrey NIKIPELOV, Eindhoven (NL); Dmitry KURILOVICH, ‘s-Hertogenbosch (NL)

(73) Assignee: ASML NETHERLANDS B.V., Veldhoven (NL)

(21) Appl. No.: 17/768,280

(22) PCT Filed: Aug. 25, 2020
(86) PCT No.: PCT/EP2020/073669

§ 371 Date: Apr. 12, 2022

(30) Foreign Application Priority Data
Oct. 18, 2019 (EP) 19204036.8

(51) Int. Cl. G03F 1/82; G03F 1/64

(52) U.S. Cl. CPC G03F 1/82; G03F 1/64

(57) ABSTRACT

A membrane cleaning apparatus for removing particles from a membrane, the apparatus including: a membrane support for supporting the membrane; and a pressure pulse generating mechanism including one or more laser energy sources configured to generate a pressure pulse in a gas. The one or more energy laser sources may be focused to generate a pressure pulse in a gaseous atmosphere. The pressure pulse serves to dislodge particles on the membrane.

### CROSS-REFERENCE TO RELATED APPLICATIONS

This application claims priority of EP application 19204036.8 which was filed on Oct. 18, 2019 and which is incorporated herein in its entirety by reference.

### FIELD

The present invention relates to a membrane cleaning apparatus and an associated method. The apparatus and method have particular application for cleaning a pellicle used in a lithographic apparatus.

### BACKGROUND

A lithographic apparatus is a machine constructed to apply a desired pattern onto a substrate. A lithographic apparatus may, for example, project a pattern provided on a patterning device (e.g., a mask) onto a layer of radiation-sensitive material provided on a substrate (e.g., a silicon wafer). A lithographic apparatus can be used in the manufacture of integrated circuits.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Unwanted particles present on a patterning device may contribute to a pattern imparted to a beam of radiation. In a lithographic apparatus, this can lead to errors in the pattern applied to the substrate. It is therefore important to prevent particles from reaching, and thereby contaminating, the patterning device. It is known to provide a membrane between a patterning device and sources of particles in a lithographic apparatus to prevent particles from reaching the patterning device. A membrane used for such a purpose is known in the art as a pellicle.

The pellicle is spaced from the patterning device such that it is not in a field plane and therefore any particles disposed on the pellicle should not be imaged (and therefore should not contribute to errors in the pattern applied to the substrate). However, particles on the pellicle may result in increased absorption of the radiation during exposure of a substrate and therefore result in local hot spots on the pellicle that may lead to failure of the pellicle. In addition, particles on a surface of the pellicle which faces the patterning device may be transferred to the patterning device whereby they can cause errors in the pattern applied to the substrate.

It may be desirable to provide an apparatus and associated method for cleaning a membrane (e.g., a pellicle).

### SUMMARY

According to a first aspect of the invention there is provided a membrane cleaning apparatus for removing particles from a membrane, the apparatus comprising: a membrane support for supporting the membrane; and a pressure pulse generating mechanism including one or more laser energy sources configured to generate a pressure pulse in a gas.

The apparatus according to the first aspect of the invention provides an arrangement wherein particles can be removed from a membrane using a pressure pulse. In use, a membrane can be supported by the membrane support. The membrane may be a pellicle membrane for use in an EUV lithography machine. The pressure pulse generating mechanism can be used to generate pressure pulse in gas contained within the apparatus. Without wishing to be bound by scientific theory, it is believed that the pulsed, or power modulated and/or focused laser beam provided to the gas causes a laser induced breakdown, also known as ‘laser spark’. Laser spark causing rapid expansion of the gas thereby generating a pressure pulse. The pressure pulse is able to propagate through the gas until it reaches the membrane where it is able to remove particles from a surface of the membrane. The particle may be dislodged by mechanical forces. The one or more laser energy sources may be any suitable laser. The use of lasers energy sources to provide a pressure pulse to the membrane allows for the equipment used to generate the pressure pulse to be remote from the membrane, which may be a pellicle membrane. In addition, lasers do not risk introducing a new source of contaminants, whereas electrodes producing electrical sparks could in fact increase the amount of particles in the apparatus. The lasers may also be pulsed to provide a sequence of pressure pulses.

The pressure pulse generating mechanism may include two or more laser energy sources. It will be appreciated that a single laser could be divided into two or more beams, which are then focused onto a predetermined position within the apparatus in order to generate the pressure pulse. It will also be appreciated that a single laser beam may be focused such that the focal point is at a predetermined location. In this way there is a maximum intensity of laser light at this location, which serves as the epicenter of the pressure pulse. There may alternatively or additionally be two or more individual lasers included in the apparatus. The beams from the two or more individual lasers may be focused onto a predetermined position within the apparatus to generate the pressure pulse. Any wavelength of laser light may be used as long as it is able to be absorbed by the gas within the apparatus in order to cause the gas to expand, following laser induced breakdown and subsequent, fast plasma thermalization.

The one or more laser energy sources may be directed at a predetermined location to generate a pressure pulse. Additionally or alternatively, the pressure pulse is produced via laser induced breakdown in the gas. Since it is desirable to generate the pressure pulse at a specific location, the one or more laser energy sources may be focused at a predetermined location such that there is an increased energy density at the location at which the pressure pulse is generated. It will be appreciated that the one or more laser energy sources may be focused at the predetermined location and/or may be reflected such that they overlap at the predetermined location. Focusing the one or more laser energy sources (lasers) at the predetermined location means that the laser beam(s) diverge past the focal point. As such, any laser light which hits the membrane is of lower intensity and the pellicle membrane remains undamaged. The laser beam or beams may be focused by any suitable means, such as a lens or a reflective focusing element. The focusing means can be located away from the membrane to avoid the risk of inadvertent contact with the membrane.

It will be appreciated, that laser energy is coupled to a laser spark only partially (typically, 10-90%). So, even in the case of laser induced breakdown, a significant part of the laser fluence is delivered to the pellicle and may cause direct damage or at least significant heating if absorbed. In order to reduce such heating, the laser may be directed to the pellicle at grazing incidence (typically, less than 45 degrees, less than 30 degrees or less than 20 degrees). In this way, the pellicle reflectivity can be boosted. Alternatively, or additionally, a masking device may be provided to intercept or reflect (directional) laser beam energy, while transmitting a portion of the pressure pulse towards the pellicle.

The apparatus comprises a gaseous atmosphere in which the pressure pulse is generated. Since it is the physical force provided by the gas which serves to remove particles from the membrane, it is necessary for the gas to be in contact with the membrane in order to transmit the force. The gas also absorbs the laser energy to generate the pressure pulse.

The gaseous atmosphere may be at any suitable pressure. The pressure may be from about 0.1 bar to about 10 bar. The pressure of the gas may be adjusted depending on the type of laser used and the desired force applied to the membrane. A higher pressure gas allows easier generation of the pressure pulse, but a higher pressure means that any dislodged particles are less able to travel through the gas before losing speed and may settle back on the membrane. Conversely, a lower pressure allows dislodged particles to travel away from the membrane more easily, but makes generation of the pressure pulse more difficult.

The gaseous atmosphere may comprise an inert gas. An inert gas is one which does not react with the membrane, or at least reacts reversibly. The inert gas may be selected for example, from hydrogen, nitrogen, noble gases, or mixtures thereof. These gases are readily available and do not chemically change the membrane.

The gaseous atmosphere may be substantially free of oxygen, water, or any other oxygen containing species. The membrane may be susceptible to oxidation or otherwise damaged by the presence of such species. It will be appreciated that there may be trace levels of such species due to contamination or impurities.

The apparatus may comprise focusing means to focus one or more laser beams at a predetermined location. The laser beams are generated by the laser energy sources, which may simply be referred to as lasers. Any suitable focusing means may be used. The focusing may be effected by mirrors and/or optical lenses. The predetermined location is the location from which it is desired for the pressure pulse to propagate. The highest laser intensity is at the focal point of the laser. This intensity is high enough to generate a laser spark which generates the pressure pulse. The apparatus may be configured to translate the predetermined location or locations with respect to the membrane. By being able to adjust or move the predetermined location, it is possible to provide a pressure pulse to different portions of the membrane. The predetermined location may be translated by relative movement of the apparatus and the membrane and/or by any other suitable means. It will be appreciated that the invention is not particularly limited by the means used.

Prior to cleaning, there may be a step of particle mapping. This particle mapping confirms the locations of the particles and it is possible to therefore determine the nature and location of the pressure pulse applied during cleaning of the membrane.

The apparatus may be configured to generate the pressure pulse at a distance of around 1 mm to around 100 mm, preferably around 5 mm to around 50 mm from the membrane. By generating the pressure pulse a distance away from the membrane, this ensures that any ions or plasma generated by the laser induced breakdown of the gas do not reach the membrane. In addition, the distance from the location of the generation of the pressure pulse, which may be a focal point of the laser, can be selected and/or adjusted to adjust the time taken for the pressure pulse to arrive at the membrane. In embodiments where a pressure pulse is provided to both sides of the membrane, it may be desirable to provide the pressure pulses at different times. It is therefore possible to control the timing of the pressure pulses by selecting and/or adjusting the location at which the pressure pulses are generated. It will also be appreciated that the timing of the pressure pulses arriving at the membrane may also be controlled by the timing of the laser pulses which generate the pressure pulses.

The apparatus may be configured to provide at least one pressure pulse to each side of the membrane. If a pressure pulse is applied to just one side of the membrane, this may exceed the mechanical strength of the membrane and cause damage or rupture. This may be caused by over-deflection of the membrane. By providing a pressure pulse to each side of the membrane, the risk of over-deflection is addressed since the overall forces on the membrane are balanced. Preferably, the magnitude of the pressure pulses applied to each side of the membrane are substantially equal.

The apparatus may be configured to provide at least one pressure pulse to each side of the membrane asynchronously. By providing the pressure pulses asynchronously, the membrane is deflected in one direction by the first pressure pulse and is then deflected in the opposite direction by the second pressure pulse. In this way, damage or rupture of the membrane is avoided by the second pressure pulse which balances the force of the first pressure pulse before the membrane is over-deflected. The apparatus may additionally or alternatively be configured to provide at least one pressure pulse to each side of the membrane synchronously. Although the pressure pulses will cancel one another out such that there is minimal or no deflection of the membrane in the direction of the frontmost portions of the pressure pulses, the shear forces causes by the grazing propagation of the pressure pulse(s) can also serve to dislodge particles from the membrane. This is because the pressure pulses can be thought of as spherical rather than linear. As such, only the portion of the membrane which is closest to the point of origin of the pressure pulse experiences a pressure pulse which is perpendicular to the surface of the membrane, with the adjacent areas experiencing a pressure pulse with both a perpendicular and lateral component. The lateral component of the pressure pulse is able to move particles along and away from the surface of the membrane. It will be appreciated that the apparatus may be configured to select whether the pressure pulses are provided synchronously or asynchronously as desired. In use, the apparatus may provide synchronous or asynchronous pressure pulses at different stages of the cleaning process.

The apparatus may comprise one or more masking units configured to allow a portion of a pressure pulse therethrough. As mentioned, the pressure pulse is in the form of a spherical wavefront. The masking unit allows only a portion of the spherical wavefront through such that only a segment of the original spherical wavefront reaches the membrane. In this way, the force applied by the pressure pulse can be limited to a selected area of the membrane. The masking unit may be in the form of a plate with an opening which allows the pressure pulse to pass through. The dimension and shape of the opening may be selected to allow a particular dimension or shape of the pressure pulse through. By providing the pressure pulse to a selected portion of the membrane, it is possible to apply a higher pressure than would otherwise be the case. If the high pressure were applied to the entirety of the membrane, this could risk damage or failure of the membrane. Additionally, the mask may partially or fully block or redirect the diverging part of the laser beam (after the beam waist) and reduce the thermal load on the pellicle.

One or more masking units, which may be referred to as simply masks, may be provided on each side of the membrane. It may be desirable to balance the forces applied to each side of the membrane, so in order to do this and avoid any substantial pressure differential across the membrane, a masking unit may be provided on each side.

The apparatus may be configured to generate a plurality of pressure pulses, the plurality of pressure pulses being arranged to cause constructive and or destructive interference to provide a pressure pulse to a portion of the membrane. As such, this is an alternative or additional way in which the pressure pulse can be selectively provided to the membrane.

The apparatus may be configured to generate a plurality of pressure pulses at a uniform distance from a particle on the membrane. By providing a plurality of pulses at a uniform distance from a particle on the membrane, the front of each pressure pulse will arrive at the particle at the same time and will coherently add to provide a stronger “punch” to the particle. The waves may destructively interfere in the area around the particle.

The apparatus may be configured to generate the plurality of pulses simultaneously. In this way, the various pressure pulses arrive at the membrane simultaneously and can effectively dislodge a particle on the membrane.

The apparatus may comprise a reflector configured to reflect at least a portion of a pressure pulse to a secondary focus location. In this way, the original pressure pulse can be imaged at the secondary focus location to provide a “virtual” pressure pulse at the desired distance from the membrane. This allows the laser to be focused even further away from the membrane to reduce the possibility of any plasma or ions generated by the laser beam from reaching the membrane. The reflector may be in the form of a concave reflective surface. The reflective surface may be shaped such that an original pressure pulse generated at a first focus of the concave surface is then focused at the second focus of the concave surface. The reflector unit may comprise an opening configured to allow a laser beam to pass therethrough.

The apparatus may further comprise a particle adsorption surface disposed adjacent the membrane. The apparatus of the present invention is configured to dislodge particles from a membrane. The dislodged particles may re-settle onto the membrane after they have been dislodged. This is especially the case if there is a high pressure of gas, such as above atmospheric pressure, which causes the particles to lose speed quickly so there is a higher chance of the particles returning to the membrane. Since the particles attach to surfaces via Van der Waals interactions, any surface is suitable. The particle adsorption surface may comprise a polymer, such as Teflon®, polyurethane, polyethylene, or the like. The particle adsorption surface may comprise fibres. The particle adsorption surface may be located any suitable distance from the membrane. The particle adsorption surface may be located around 0.3 mm to 30 mm, typically about 10 mm from the membrane. The particle adsorption surface may be substantially parallel to the membrane. The particle adsorption surface may also act as a mask for the pressure pulses, as discussed above. Alternatively, the particle adsorption surface may also be transparent and allow the laser beam towards the membrane.

The apparatus may be configured to flow gas across one or both faces of the membrane. The gas may be hydrogen. Providing a flow of gas entrains any dislodged particles and carries them away from the membrane. This avoids the particles settling back onto the membrane. Hydrogen is preferably used as this is a common gas used with such membranes and does not damage the membrane. Other gases, such as nitrogen or noble gases or mixtures of gases may be used.

The pressure pulse generating mechanism may be operable to remove particles with a dimension between about 0.1 and about 10 microns from the membrane. It will be appreciated that the term pressure pulse generating mechanism is not intended to imply any mechanical moving parts. The pressure pulse generating mechanism may rely on stationary elements to generate the pressure pulse.

The apparatus may be configured to provide a plurality of temporally spaced pressure pulses. Since a single pressure pulse may be insufficient to dislodge a particle from the membrane, it may be necessary to apply multiple pressure pulses to dislodge a particle. This may be achieved by providing a pulsed laser beam.

The laser energy sources (lasers) may have a power of about 0.1 mJ to about 150 mJ. The amount of power provided will depend on the desired magnitude of the pressure pulse.

The laser energy may be provided in pulses. The pulses may be nanosecond or picosecond pulses. The laser pulse duration may be less than or equal to around 100 ns. Preferably, the laser pulse duration is in the range 10 ps to 100 ns. The frequency of the pulses can be selected as required.

The apparatus may be configured to induce oscillations only in a localized portion of the membrane. By constraining the mechanical oscillations to a localised portion of the membrane a more precise, quicker and more energy efficient cleaning process may be achieved.

The apparatus may be configured to move the point of generation of the pressure pulse relative to the membrane. In this way, different portions of the membrane may be cleaned.

It will be appreciated that the various features of the first aspect of the present invention may be combined with one another, except where such features are mutually exclusive, and so all combinations are explicitly considered and described.

According to a second aspect of the invention there is provided a method for removing particles from a membrane, the method comprising generating a pressure pulse in a gas which is in contact with the membrane to exert a mechanical force on any particles disposed on the surface of the membrane.

By using a gas to provide the force to the particle, it is not necessary to have electrodes to provide electrostatic forces which act upon the membrane to dislodge particles. The gas can also serve to transport dislodged particles away from the membrane. The gas can also disperse any ions or plasma generated by the creation of the pressure pulse by the laser spark.

The pressure pulse may be generated by focusing one or more laser energy beams at a predetermined location within the gas. As described in respect of the first aspect of the present invention, the focused laser beam causes the gas to expand and thereby generates a pressure pulse within the gas. When the pressure pulse impacts the membrane, particles disposed on the membrane are dislodged.

One or more pressure pulses may be generated on either side of the membrane. Since the pressure pulses are generated on each side of the membrane, there is a reduced risk of there being a pressure imbalance across the membrane, which could lead to damage or rupture of the membrane.

The generation of the one or more pressure pulses may be timed and/or located such that a pressure pulse from each side of the membrane arrives at the membrane simultaneously or non-simultaneously. As described in respect of the first aspect, it may be desirable to have pressure pulses arrive at the membrane simultaneously or non-simultaneously. The time of arrival of a pressure pulse is determined by the distance from the membrane and the time the pressure pulse is generated (this is assuming that the velocity of each pressure pulse is the same). As such, in order to produce pressure pulses which arrive at asynchronously, the pressure pulses could be generated at the same time but at different distances from the membrane, or at the same distance from the membrane but at different times. It will also be appreciated that pressure pulses may arrive synchronously at the membrane where they are generated at the same time and distance from the membrane.

The pressure pulse may be passed through an opening before arriving at the membrane. The opening may be disposed in a masking unit. The opening allows only a portion of the pressure pulse through. In this way, the pressure pulse can be provided to only a portion of the membrane. Particularly, it is beneficial to provide laser beam (including focusing) at the grazing incidence to the pellicle membrane and optionally the masking unit, in order to partially or fully block/redirect the partially transmitted laser beam away from the pellicle membrane while allowing a portion of the pressure pulse to reach the pellicle membrane.

A plurality of pressure pulses may be generated on one or both sides of the membrane. The individual pressure pulses may be generated at a uniform distance from the membrane. As described in respect of the first aspect of the present invention, this allows for there to be constructive interference between the various pressure pulses at a portion of the surface of the membrane, preferably at or near to any particle on the membrane.

The pressure pulse may be reflected off a reflecting element and focused at a secondary focus location. This allows the pressure pulse to be generated at a location remote from the membrane, which decreases the likelihood that the membrane will be physically damaged by, for example, contact with the apparatus, or damaged by any plasma or ions generated by the laser creating the pressure pulse.

The method according to the second aspect of the invention may use the apparatus according to the first aspect of the invention.

### BRIEF DESCRIPTION OF THE DRAWINGS

Embodiments of the invention will now be described, by way of example only, with reference to the accompanying schematic drawings, in which:

FIG. 1 shows a lithographic system, demonstrating a pellicle in use;

FIG. 2 shows an embodiment of a membrane cleaning apparatus according to the invention in which a pressure pulse is provided on both sides of a membrane asynchronously;

FIG. 3 shows an embodiment of a membrane cleaning apparatus according to the invention including a masking unit;

FIG. 4 shows an embodiment of a membrane cleaning apparatus according to the invention in which a pressure pulse is provided on both sides of a membrane synchronously;

FIG. 5 shows an embodiment of a membrane cleaning apparatus according to the invention in which a plurality of pressure pulses is generated at a uniform distance from a membrane; and

FIG. 6 shows an embodiment of a membrane cleaning apparatus according to the invention including a reflector.

### DETAILED DESCRIPTION

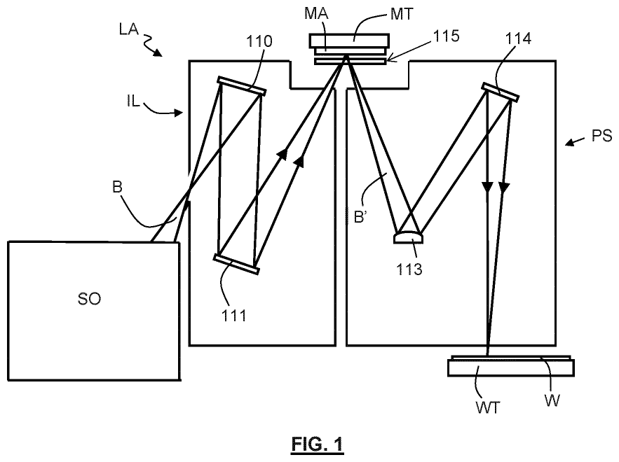

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 110 and a facetted pupil mirror device 111. The faceted field mirror device 110 and faceted pupil mirror device 111 together provide the EUV radiation beam B with a desired cross-sectional shape and a desired intensity distribution. The illumination system IL may include other mirrors or devices in addition to, or instead of, the faceted field mirror device 110 and faceted pupil mirror device 111.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 113, 114 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 113, 114 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e., a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

Some lithographic apparatus (e.g., EUV and DUV lithographic apparatus) comprise a pellicle 115. The pellicle 115 may be attached to the support structure MT or, alternatively, the pellicle 115 may be attached directly to the patterning device MA. The pellicle 115 comprises a thin membrane of transmissive film (typically less than about 70 nm) mounted on a frame. The pellicle membrane is spaced a few mm (typically less than 10 mm, for example 2 mm) away from the patterning device MA. A particle which is received on the pellicle membrane is in the far field with respect to the pattern of the patterning device MA, and consequently does not have a significant impact upon the quality of image which is projected by the lithographic apparatus LA on to a substrate W. If the pellicle 115 were not present, such particles may lie on the patterning device MA and would obscure a portion of the pattern on the patterning device MA, thereby preventing the pattern from being projected correctly on to the substrate W. The pellicle 115 thus plays an important role in preventing particles from adversely affecting the image formed on a substrate W by the lithographic apparatus LA.

Before the pellicle 115 is attached to the support structure MT or the patterning device MA for use in a lithographic apparatus LA, the pellicle membrane may become dirty. That is, particles may be incident on the pellicle membrane before the pellicle 115 is used in a lithographic apparatus LA as described above. Activities such as transporting the pellicle 115, packaging the pellicle 115, and mounting the pellicle membrane to a frame may result in particles being incident upon the pellicle membrane.

It has been found that some particles that are present on the pellicle membrane detach and travel from the pellicle membrane to the patterning device MA during a lithographic exposure, and thereby negatively affect the pattern projected onto the substrate W. Particles with a dimension between 0.5 um and 5 um have been reported to move. It will be appreciated that, in other setups, particles with one or more dimensions outside of this range may move.

A pellicle 115 may be formed from one or more layers, which may be formed on a support substrate. The support substrate allows the thin membrane of the pellicle 115 to be formed without risking the membrane rupturing. Once the layers of the membrane have been formed, the support substrate can be removed (for example by etching) to form the final thickness of the membrane. Pellicles 115 with membranes that are found to be too dirty for use may be discarded. Whilst there exists some methods for cleaning pellicles 115, these are typically used before the final thickness of the membrane has been achieved, that is when the membrane is still disposed on the support substrate. These known methods for pellicle cleaning include wet cleaning or applying heat. However, the known methods are unsuitable for use once the final thickness of the membrane has been achieved since they risk rupturing the thin pellicle membrane. Furthermore, cleaning methods that involve applying heat may also contribute to a weakening of the pellicle membrane, thereby reducing the operational lifetime of the pellicle 115, mostly due to stress at interfaces of materials with different coefficients of thermal expansion and/or due to temperature inhomogeneity translating to mechanical stress.

Embodiments of the present invention relate to apparatus and associated methods for removing particles from a membrane using a pressure pulse in a gas to dislodge particles from the membrane, which may be a pellicle membrane. In particular, some embodiments of the present invention are particularly well suited and adapted to cleaning relatively thin membranes (such as, for example, pellicle membranes), which are fragile.

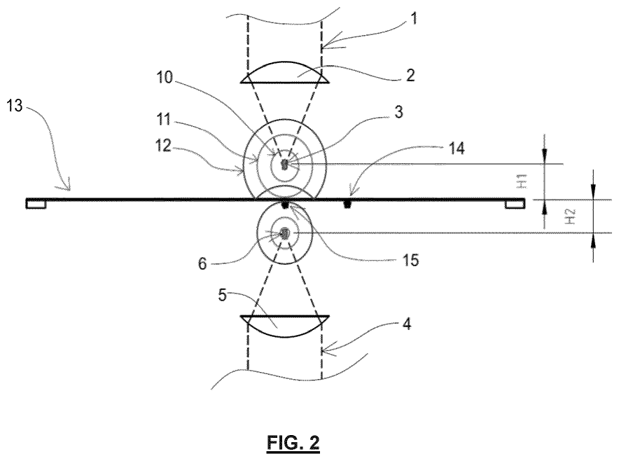

Some embodiments of the present invention exploit the fact that relatively thin membranes (such as, for example, pellicle membranes) are relatively flexible, by inducing mechanical oscillations in the membrane. In turn, this will also induce mechanical oscillations in particles situated on the membrane. This oscillation of such particles situated on the membrane may be sufficiently large to remove particles from the membrane. In turn, any such particles which are removed by the mechanism for inducing mechanical oscillations may be transported away from the membrane by a gas flow or may be captured by a surface other than the membrane. Examples of such embodiments are now described with reference to FIGS. 2 to 6.

A membrane cleaning apparatus according to the present invention is now described with reference to FIGS. 2 to 6. Although the Figures depict various configurations of the apparatus, it will be appreciated that the various specific configurations may be combined with one another and all such combinations are explicitly considered and disclosed.

FIG. 2 depicts an embodiment of the membrane cleaning apparatus. A laser beam 1 is provided from a laser energy source (not shown). The laser beam 1 is focused by optical element 2, which may be a lens, to focal point 3. On the other side of the membrane 13, there is also provided a laser beam 4 provided from a laser energy source (not shown) as well as a second optical element 5, which may be a lens, that is configured to focus the laser beam to focal point 6. It will be appreciated that although the figure depicts a laser beam and an optical element on both sides of the membrane 13, that in some embodiments such elements may be provided on only one side of the membrane 13.

In use, the laser beams 1, 4 are focused at focal points 3, 6 which both lie above the surface of the membrane 13. The gas present at the focal points 3, 6 is heated by the laser energy, which causes the gas to expand. The focused, pulsed laser beams 1, 4 give rise to a pressure pulse. The propagating front of the pressure pulse (also known as a shock wave) is shown in different time instances as 10, 11, 12. The shock wave propagates through the gas and arrives at the membrane 13. In the depicted configuration, the distance H1 between the laser spark at focal point 3 and the membrane 13 is different to the distance H2 between the laser spark at focal point 6. As such, even if the pressure pulses emanating from the two focal points 3, 6 are generated simultaneously, the generated pressure pulses arrive at the membrane 13 at different times. In this way, the membrane 13 is deflected in one direction by the first pressure pulse to arrive and then in the other direction by the second pressure pulse to arrive. This prevents the membrane 13 from damage by over-deflection. It will also be appreciated that the arrival of pressure pulses may also be controlled by controlling the timing of the provision of the laser energy pulses which generate the pressure pulses. FIG. 2 depicts a first particle 15 and a second particle 14. The location of the focal points 3, 6 may be adjusted such that a particle which is desired to be removed is at a location normal to the pressure pulses. Similarly, the distance H1, H2 between the focal points and the membrane 13 can be adjusted. Particles, such as particle 14, which are not normal or aligned with the pressure pulses may remain on the membrane 13 as the pressure pulse may have reduced in intensity. The apparatus may be configured to allow relative movement of the membrane cleaning apparatus and the membrane to allow different areas of the membrane to be cleaned. Since the laser beams 1, 4 are focused above the surface of the membrane 13, any laser energy which is not absorbed by the gas to produce the shockwave and which arrives at the membrane 13 has diverged. In this way, the intensity of the incident laser energy on the membrane 13 is reduced to below a level which can damage the membrane 13. Further, if for some reason a laser spark is not generated, and thereby laser energy is not significantly absorbed by the gas, focusing the laser beam above the membrane 13 allows for beam divergence. The fluence may be below 0.1 J/cm², or even below 0.01 J/cm². The pellicle absorption of the laser energy (with or without the laser spark) may further be reduced in the case laser beam is directed to the pellicle at a grazing incidence, for example less than 20 degrees (not shown).

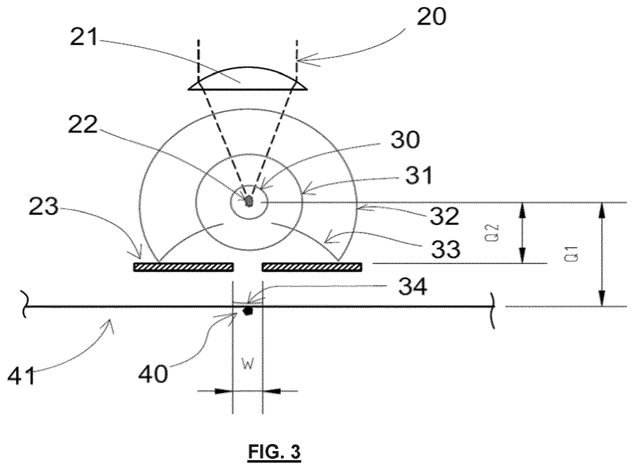

FIG. 3 depicts an embodiment of the present invention in which a masking unit or masking plate 23 is provided. It will be appreciated that any of the configurations depicted in the Figures can comprise one or more masking units or masking plates 23. For example, the configuration of FIG. 2 may comprise a masking plate on one or both sides of the membrane 41. As with FIG. 2, the apparatus includes a laser energy source (not shown) which generates a laser beam 20 that is focused by an optic 21. At the focal point 22 of the laser beam, a laser spark is generated by the absorption of energy from the laser beam by the gas present at the focal point 22. This generates a pressure pulse. A resulting shock wave position at subsequent time instances is shown as 30, 31, 32. The masking plate 23 is disposed between the membrane 41 and the focal point 22. The masking plate 23 include an opening which allows a portion 34 of the pressure pulse through. The portion 34 of the pressure pulse which is transmitted through the masking plate 23 is directed to the membrane 41 at a location of a particle 40 in order to dislodge the particle 40. The masking plate may also serve to partially or fully block/redirect laser beam away from the pellicle (not shown).

The distance Q2 from the focal point 22 to the mask 23 may be from around 1 cm to around 10 cm, although other distances could be used if necessary. The distance Q1-Q2, namely the distance between the membrane 41 and the mask 23 may be from around 1 mm to around 10 mm, although other distances could be used if necessary. The mask opening size W may be from around 1 mm to around 10 mm, although other sizes could be used if necessary. In such configurations, the pressure pulse delivered to the membrane 41 may deliver a pressure of from about 1 kPa to about 10 kPa to the membrane 41 over an area of from around 1 to around 100 mm². A mask 23 may reflect a portion 33 of a pressure pulse 30, 31, 32. By only providing a portion 34 of the pressure pulse to the membrane 41, the overall force applied to the membrane 41 is reduced, which reduces the likelihood that the membrane 41 will be damaged or rupture.

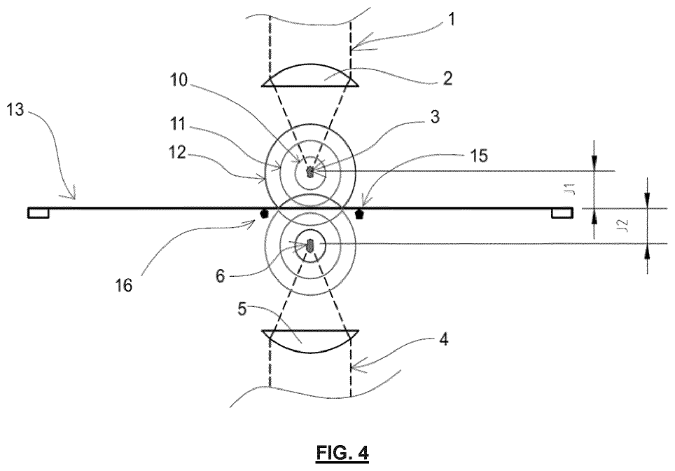

FIG. 4 depicts a configuration of the present invention in which the apparatus is arranged to provide synchronous pressure pulses to a membrane 13. It will be appreciated that this configuration is similar to that of FIG. 2 and so corresponding numbering is used. FIG. 4 differs from FIG. 2 in that the distance J1, J2 between the laser sparks at the focal points 3, 6 on either side of the membrane 13 are equal, i.e. J1 and J2 are equal. As such, where the laser beam pulses are provided simultaneously, the time taken for the generated pressure pulses to arrive at the membrane 13 is equal. The normal forces applied to the membrane 13 by the synchronously arriving pressure pulses cancel one another out, so there is no risk of rupture of the membrane 13. Particles 15, 16 may be removed from the membrane by the shear forces of the synchronously arriving pressure pulses. Although the normal pressure pulses will cancel one another out, since the pressure pulses comprise a spherical wavefront, portions of the pressure pulse which are not normal to the pressure pulse, will comprise a lateral component. The lateral component of the pressure pulses is able to move the particles 15, 16 along the membrane and dislodge the particles. It will be appreciated that the apparatus of FIG. 4 may include the masks of FIG. 3.

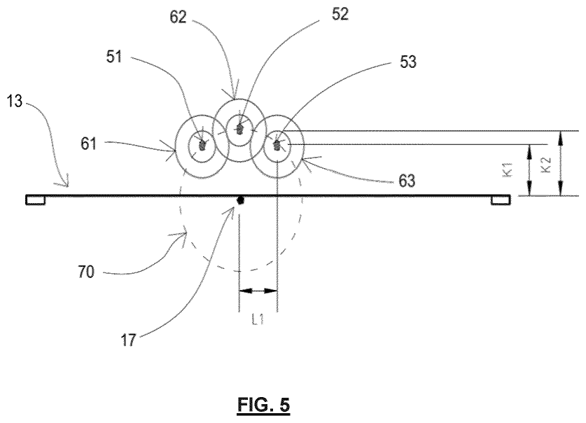

FIG. 5 depicts another configuration of the apparatus according to the present invention. In this configuration, the apparatus is configured to generate a plurality of pressure pulses 61, 61, 63, each emanating from a focus point 51, 52, 53. In the depiction, there are three sources of pressure pulse, but it will be appreciated that fewer or more than three pressure pulses can be used. This may be achieved by any suitable means, such as the provision of multiple laser energy sources or by dividing a laser beam into multiple beams. As depicted, the different focal points 51, 52, 53 may be located at a uniform distance from the particle to be removed. As such, the focal points 51, 52, 53 may be located on the surface of an imaginary sphere centred on the particle to be removed. In this way, the pressure pulses coherently add at the location of the particle, providing the particle with a focused “kick” to dislodge the particle from the membrane 13. In this way, although the vertical distances K1, K2, between the focal points 51, 52, 53 and the membrane 13 may not be the same, and although there may be a lateral spacing L1 from the particle, these two values are selected such that the distance between the focal points and the particle are uniform. As with all of the other figures, the configuration depicted in FIG. 5 may include any of the features depicted in the other figure or described herein. For example, there may be a mask disposed between the membrane 13 and the focal points in order to only allow a portion of the pressure pulses through. The shape and dimensions of an opening in the mask may be selected to allow a desired portion of the pressure pulses through.

It will be appreciated that the greater the number of pressure pulses which are provided, the more precisely the force can be provided to the particle. As with the other figures, it will be appreciated that the pressure pulses could be provided on both sides of the membrane.

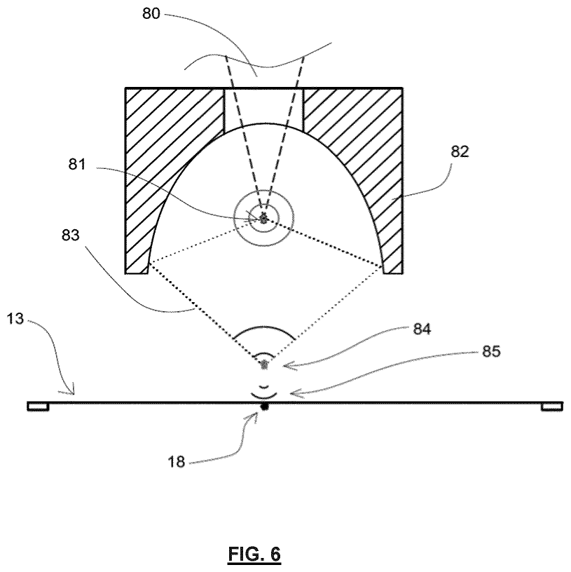

FIG. 6 depicts a configuration in which the laser spark is generated at a location remote from the membrane 13 and the generated pressure pulse is focused by focusing element 82 to a point 84 closer to the membrane 13. The focusing element 82 includes a concave portion having a curved surface. The curved surface is shaped to reflect a pressure pulse at a desired location adjacent the membrane 13. The reflecting element 82 includes an opening which allows a focused laser beam 80 to pass through. The focused laser beam 80 is focused in order to generate a laser spark at focal point 81. The pressure pulse expands from this point until it reaches the internal wall or surface of the reflecting element 82. The reflecting element 82 is shaped to focus the pressure pulse at a second focal point 84 located closer to the surface of the membrane 13 than the first focal point 81. The initial pressure pulse may be generated at a primary focus of the curved internal wall of the focusing element 82 and focused at a secondary focus of the focusing element 82. Focusing the pressure pulse at focal point 84 produces a “virtual” laser spark which appears as a source of a pressure pulse 85 which is then able to dislodge a particle 18 from the membrane 13. In this configuration, since it is possible to focus the laser at a greater distance from the membrane 13, any laser energy which is not absorbed to produce the pressure pulse is able to diverge to a greater extent than would be the case were the initial pressure pulse generated adjacent the membrane 13. In addition, any ions or plasma generated are dispersed before reaching the membrane 13. Again, it will be appreciated that such a configuration could be provided on both sides of the membrane 13. It will also be appreciated that one or more masking units could be provided on one or both sides of the membrane 13 as herein described.

It will be appreciated that several features have been introduced in the membrane cleaning apparatus, but these features need not be used together in a single embodiment. It will be further appreciated that features of the membrane cleaning apparatus may be used in combination with features of membrane cleaning apparatuses depicted in the figures.

It will be appreciated that the membrane described herein may be a pellicle for use in an EUV lithographic apparatus. In particular, the membrane may comprise the pellicle 15, which comprises a thin membrane mounted on a frame.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions. Embodiments of the invention may be used to clean membranes other than pellicle membranes.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A membrane cleaning apparatus for removing particles from a membrane, the apparatus comprising:
a membrane support configured to support the membrane; and
a pressure pulse generating mechanism including one or more pulsed laser energy sources configured to generate a pressure pulse in a gas.

2. (canceled)

3. The apparatus of claim 1, wherein the one or more laser energy sources is focused at a predetermined location to generate a pressure pulse and/or wherein the pressure pulse is produced via laser induced breakdown in the gas.

4. The apparatus of claim 1, comprising a gaseous atmosphere comprising an inert gas.

5.-8. (canceled)

9. The apparatus of claim 1, further comprising a focusing structure to focus one or more laser beams at a predetermined location.

10. The apparatus of claim 1, configured to generate the pressure pulse at a distance of around 1 mm to around 100 mm from the membrane.

11. The apparatus of claim 1, configured to provide at least one pressure pulse to each side of the membrane.

12. (canceled)

13. The apparatus of claim 1, further comprising one or more masking units configured to allow a portion of a pressure pulse therethrough, and/or further comprising one or more masking units configured to at least partially block or redirect laser radiation away from the membrane.

14. The apparatus of claim 13, wherein the one or more masking units is configured to partially block pressure pulses propagating towards the membrane

15. The apparatus of claim 13, wherein one or ore masking units is provided on each side of the membrane.

16. The apparatus of claim 1, configured to generate a plurality of pressure pulses, the plurality of pressure pulses being arranged to cause constructive and/or destructive interference to provide a pressure pulse to a portion of the membrane.

17.-18. (canceled)

19. The apparatus of claim 1, further comprising a reflector configured to reflect at least a portion of a pressure pulse to a secondary focus location.

20. The apparatus according to claim 1, further comprising a particle adsorption surface disposed adjacent the membrane.

21.-23. (canceled)

24. The apparatus of claim 1, wherein the one or more laser energy sources have a power of about 0.1 mJ to about 150 mJ and/or wherein a laser pulse duration produced by the one or more laser energy sources is less than or equal to around 100 ns.

25. The apparatus of claim 1, configured to induce oscillations only in a localised portion of the membrane.

26. The apparatus of claim 1, wherein a laser beam produced by the one or more laser energy sources is directed to the membrane at grazing incidence.

27. (canceled)

28. The apparatus of claim 1, further comprising a masking device configured to intercept or reflect laser beam energy whilst still transmitting at least a portion of the pressure pulse towards the membrane.

29. A method for removing particles from a membrane, the method comprising:
generating a pressure pulse in a gas which is in contact with the membrane to exert a mechanical force on any particles disposed on a surface of the membrane.

30. The method of claim 29, wherein the pressure pulse is generated by focusing one or more laser energy beams at a predetermined location within the gas.

31. The method of claim 29, comprising generating one or more pressure pulses on either side of the membrane.

32.-34. (canceled)

35. The method of claim 29, wherein the pressure pulse is reflected off a reflecting element and focused at a secondary focus location.

36. (canceled)
